(19) United States
(12) Patent Application Publication
(10) Pub. No.: US 2004/0253760 A1
(43) Pub. Date: Dec. 16, 2004

(54) Method to fabricate a highly perforated silicon diaphragm with controlable thickness and low stress

(75) Inventors: Qingxin Zhang, Singapore (SG); Zhe Wang, Singapore (SG)

Correspondence Address: Anthony G Sitko, Marshall Gerstein & Borun, 6300 Sears Tower, 233 South Wacker Drive, Chicago, IL, 60606-6357, US

(73) Assignee: Agency For Science, Technology And Research

(21) Appl. No.: 10/462,310

(22) Filed: Jun. 13, 2003

(51) Int. Cl. H01L 21/00

(52) U.S. Cl. 438/53

(57) ABSTRACT

A method of fabricating a highly perforated silicon diaphragm is described. A single crystal silicon substrate of a first conductivity type is provided. First ions of a second conductivity type opposite the first conductivity type are implanted into the single crystal silicon substrate to form an etch stop layer. Second ions of the first conductivity type are selectively implanted into the single crystal silicon substrate to form a pattern of holes in a portion of the substrate. Third ions of the first conductivity type are implanted overlying the pattern of holes and forming a first ohmic contact region. Fourth ions of the second conductivity type are implanted into the substrate not surrounding the pattern of holes to form a second ohmic contact region. A nitride layer is deposited on a frontside and a backside of the silicon substrate. Contacts are formed through the nitride layer to the first and second ohmic contact regions. Thereafter, the backside nitride layer is patterned and from the backside, the silicon substrate not covered by the nitride layer is etched away to the etch stop layer and, simultaneously, the pattern of holes is selectively etched away to complete formation of a perforated diaphragm.

### BACKGROUND OF THE INVENTION

1. Field of the Invention

The invention relates to a method of manufacturing a silicon diaphragm, and more particularly, to a method of manufacturing a highly perforated silicon diaphragm in micro-electro-mechanical-system (MEMS) technology.

2. Description of the Prior Art

A perforated silicon diaphragm is a very important silicon microstructure in MEMS devices such as silicon microphones, microfilters, and silicon micro-relays. In silicon microphones, a perforated silicon backplate shows significant positive characteristics when compared with other materials such as metal, silicon nitride, and polysilicon because of its excellent properties of low stress, high thermal/mechanical stability, and strong stiffness. In recent applications, a microsieve is another example of the use of a perforated diaphragm. In such an application, the silicon diaphragm is used as a microfiltration membrane to filter yeast cells in biomedical technologies. The membrane is required to be as thin as possible and the porosity should be very high to achieve small membrane resistance while keeping the membrane strong enough.

In practice, silicon diaphragms are fabricated from the wafer backside, and the small opening holes are opened from the front side by either a dry or a wet etching process. As the backside silicon etching is time controlled, so the diaphragm thickness control is quite difficult and a thin diaphragm (1-2 microns) is difficult to obtain. Furthermore, opening the wafer on the front side effects the wafer surface profile, making the device process more difficult. Efforts so far in the field are either CMOS compatible processes or non-CMOS compatible processes that can provide a very thin, highly perforated silicon diaphragm with low stress.

Various methods have been adopted to fabricate highly perforated silicon diaphragms. These methods can be divided into two major application fields: silicon microphones and microsieves for biomedical technologies.

In the field of silicon microphones, J. Bergqvist et al, “A Silicon Condenser Microphone with a Highly Perforated Backplate,” Proceedings of the 6^{th} International Conference on Solid-State Sensors and Actuators (Transducers '91), San Francisco, Calif., USA, Jun. 24-28, 1991, p. 266-269, and Quanbo Zou et al, “Theoretical and Experimental Studies of Single-Chip-Processed Miniature Silicon Condenser Microphone with Corrugated Diaphragm,” Sensors and Actuators, A63 (1997), p. 209-215, developed perforated silicon diaphragm structures which serve as backplates in their microphone designs. They used KOH wet etching or KOH plus PN etch stop techniques to form a silicon diaphragm from the wafer backside, then used either wet or dry etching to release the opening holes from the wafer frontside. As the above process involved double side silicon etch processes, the wafer frontside will have large step heights which will affect the wafer surface profile, further affecting device performance. Especially in Quanbo's design, the silicon diaphragm thickness is up to 28 microns, making it very difficult to integrate integrated circuits on the wafers. In J. Bergqvist's second version of microphone design, described in “A Silicon Condenser Microphone using Bond and Etch-back Technology,” by J. Bergqvist et al, Sensors and Actuators, A45 (1994), p. 115-124, the perforated silicon diaphragm is formed by wafer bonding techniques. Two wafers are bonded together under high temperature (1100° C.), then one wafer is thinned down using a wet etching process until 5-10 microns of silicon are left, then highly perforated holes are obtained by surface patterning, dry etching on the thinned wafer, and sacrificial layer wet releasing. The idea for fabricating a silicon diaphragm is new, but also quite complex as it involves two types of special processes: wafer to wafer bonding and wafer thinning down. Thinning the entire wafer to 5-10 microns is not easy and it is difficult to control the resulting thickness.

M. Brauer et al, “Silicon Microphone Based on Surface and Bulk Micromachining,” Journal of Micromechanics and Microengineering, 11 (2001), p. 319-322, reports another method. They produce one epitaxy layer on the wafer surface. The epitaxy layer is lightly doped, followed by trench etching and oxide filling, then the wafer is etched from the backside by KOH etching. The electrochemical etching (ECE) stops as soon as the lightly doped epitaxy layer is reached. In the final step, the sacrificial oxide inside the silicon trench is etched to release the opening holes. The fabrication process is CMOS compatible, but it is also very complex because of the epitaxy, trench etch, and trench filling processes. The wafer surface profile will be affected by the trench etch and refilling process.

A. E. Kabir et al, “Very high sensitivity acoustic transducers with thin p+ membranes and gold back-plate,” Sensors and Actuators A78, issue 2-3 (1999), p. 138-142, discusses a method for fabricating a microphone having a perforated gold backplate.

A. Dehe et al, “Silicon Micromachined Microphone Chip at Siemens,” http://www.infineon.com/news/articles/1999/0002, 1999.pdf, describes a microphone fabricated by using an epitaxial silicon substrate, boron selective doping, and forming holes by front side trench etching and oxide refilling. W. Kronast et al, “Single-chip condenser microphone using porous silicon as sacrificial layer for the air gap,” IEEE MEMS Workshop, 1998, p. 591-596 shows non-selective doping and backside patterning on a deep cavity. This deep cavity makes the process more difficult. P. C. Hsu et al, “A High Sensitivity Polysilicon Diaphragm Condenser Microphone,” IEEE MEMS Workshop, 1998, p. 580-585 teaches non-selective doping and P+ etch stop technique to fabricate a silicon backplate.

U.S. Pat. No. 6,423,474 Bi to Tai et at, also International Patent Application No. WO 97/39464, describes a thin film electret microphone fabricated as a two-piece unit that is joined together. International Patent Application No. Wo 99/24141 teaches a double side process to form a nitride silicon diaphragm having a parylene coating. International Patent Application No. WO 00/70630 shows a high performance MEMS electret microphone having a silicon nitride coated membrane or a polymeric material membrane. International Patent Application No. WO 01/78448 discloses a membrane sensor having a perforated backplate. U.S. patent application No. 2002/0106828 to Loeppert teaches a P+ type epitaxial layer backplate having vent holes.

S. Kuiper et al, “Development and Applications of Very High Flux Microfiltration Membranes,” Journal of Membrane Science, 150 (1998), p.1-8 and Cees J. M. va Rijn et al, “Micro filtration Membrane Sieve with Silicon Micro Machining for Industrial and Biomedical Applications,” IEEE MEMS Workshop,1995, p. 83-87 have developed perforated diaphragm structures for biomedical applications. In such applications, the silicon diaphragm serves as a microsieve for critical cell separation, particle analysis systems, absolute filtrations, and model experiments. In their fabrication process, one low stress LPCVD nitride layer is deposited on the wafer surface and patterned and etched via wet or dry etching processes to form small holes of about 1 μm in size. The wafer is further etched down to form a silicon trench below the nitride membrane which serves as the membrane supports to enhance the membrane stiffness. Finally, the wafer is etched through from the wafer backside to realize the perforated structure. The disadvantage of this method is that since the membrane is low stress LPCVD nitride film with a small opening attached to a perforated silicon structure, the stress in the LPCVD nitride cannot be as low as that on the single crystal silicon. It is very easy to break the membrane in the following backside etching process.

### SUMMARY OF THE INVENTION

A principal object of the present invention is to provide an effective and very manufacturable method of fabricating a silicon diaphragm having controlled thickness and low stress.

Another object of the invention is to provide a method of fabricating a silicon diaphragm using a selective doping scheme to define a low stress silicon structure.

A further object of the invention is to provide a fabrication method for a silicon diaphragm that is integrated circuitry compatible.

Yet another object of the invention is to provide a fabrication method for a silicon diaphragm wherein the diaphragm and its perforation are realized simultaneously by post-ECE processing.

In accordance with the objects of this invention a method of fabricating a highly perforated silicon diaphragm is achieved. A single crystal silicon substrate of a first conductivity type is provided. First ions of a second conductivity type opposite the first conductivity type are implanted into the single crystal silicon substrate to form an etch stop layer. Second ions of the first conductivity type are selectively implanted into the single crystal silicon substrate to form a pattern of holes in a portion of the substrate. Third ions of the first conductivity type are implanted overlying the pattern of holes and forming a first ohmic contact region. Fourth ions of the second conductivity type are implanted into the substrate not surrounding the pattern of holes to form a second ohmic contact region. A nitride layer is deposited on a frontside and a backside of the silicon substrate. Contacts are formed through the nitride layer to the first and second ohmic contact regions. Thereafter, the backside nitride layer is patterned and from the backside, the silicon substrate not covered by the nitride layer is etched away to the etch stop layer and, simultaneously, the pattern of holes is selectively etched away to complete formation of a perforated diaphragm.

### BRIEF DESCRIPTION OF THE DRAWINGS

In the accompanying drawings forming a material part of this description, there is shown:

FIGS. 1 through 7 schematically illustrate in cross-sectional representation a preferred embodiment of the present invention.

### DESCRIPTION OF THE PREFERRED EMBODIMENTS

The present invention discloses a novel process for making a highly perforated silicon diaphragm having controlled thickness and low stress. Referring now more particularly to FIG. 1, there is shown a semiconductor substrate 10, preferably composed of P-doped monocrystalline silicon. A thermal oxide layer 12 is grown on the frontside and backside surfaces of the substrate to a thickness of between about 270 and 330 Angstroms.

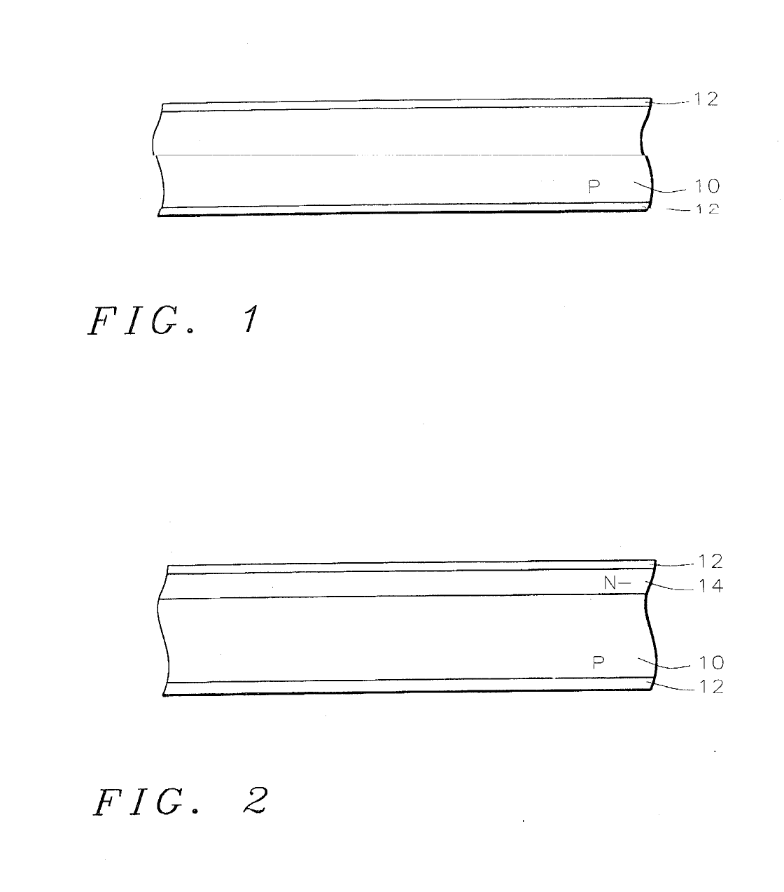

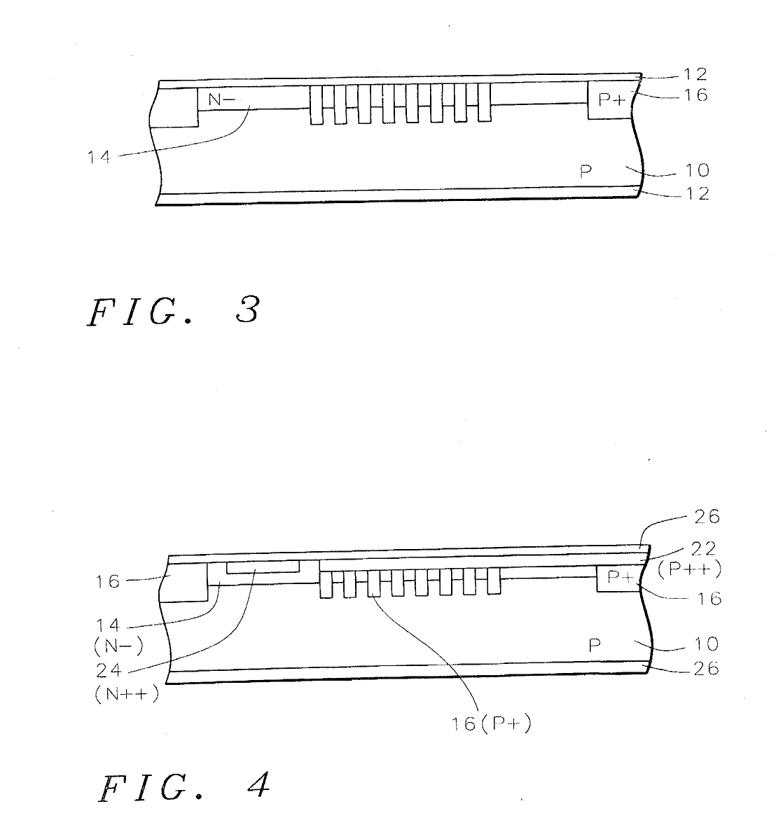

Now, the key selective doping scheme of the present invention will be described. Referring now to FIG. 2, a blanket N-implant is made through the thermal oxide layer into the upper surface of the silicon substrate 10 to form an etch stop layer. This low doping induces low stress in the silicon diaphragm.

P+ implants 16 are made through a mask, not shown. These implanted regions 16 will form acoustic holes on the backplate in a later process. The P+ implanted regions 16 are shown in FIG. 3 after a drive-in anneal. For a silicon diaphragm with targeting thickness ranging from 1 to 10 microns, the N− regions will have a depth of between about 1 to 10 microns and the P+ regions will have a depth of between about 1 to 10 microns. The higher doping only in the selective P+ doping area makes the opening the perforated holes easy while avoiding inducing additional stress in the silicon diaphragm.

Referring now to FIG. 4, a P++ implantation region 22 is formed at the surface of the substrate using a PMOS source/drain implant condition. This implantation will form an ohmic contact and connect all the P+ holes. A N++ implantation region 24 is formed elsewhere at the surface of the substrate using an NMOS source/drain implant condition to form an ohmic contact. Now, a shallow drive-in source/drain annealing is performed. The P++/N++ selective doping provides good ohmic contact to the P and N− areas, making the PN− junction function well. Furthermore, the P++ selective doping connects the perforated holes together to provide electrical biases externally for the subsequent four ECE process to insure that all of the holes will be fully opened.

The oxide layer 12 is removed and a new thermal oxide layer is grown on the frontside and backside of the wafer. A layer of nitride is deposited over the new oxide layer on the frontside and backside of the wafer. This nitride layer is deposited by low pressure chemical vapor deposition (LPCVD), for example, to a thickness of between about 1350 and 1650 Angstroms. The oxide and nitride layer together are labeled 26 in this and subsequent drawing figures.

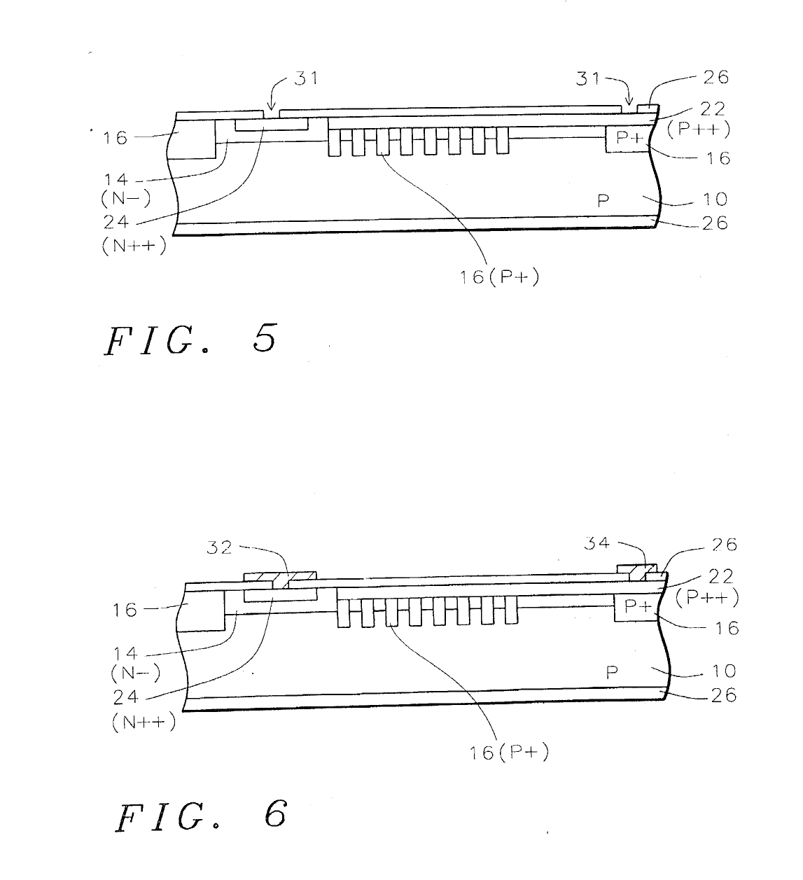

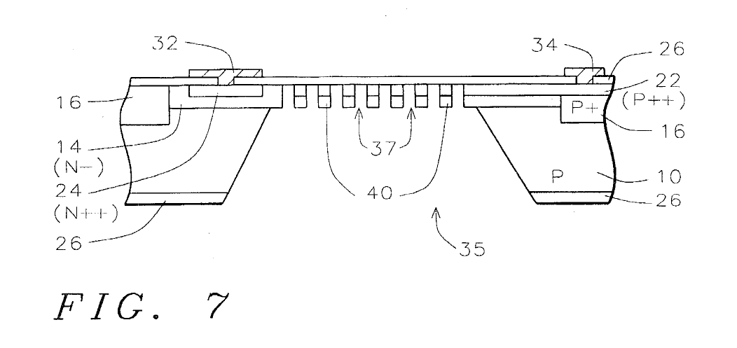

Referring now to FIG. 5, contact openings 31 are made through the nitride/oxide layer 26 on the frontside of the wafer to the N++ implanted regions 24 and to the P++ implanted region 22. A metal layer, such as aluminum, is deposited within the contact openings and over the substrate to a thickness of between about 5000 and 10,000 Angstroms. The metal layer is patterned to form N electrode 32 and P electrode 34, as shown in FIG. 6.

The backside nitride/oxide layer is patterned on the backside of the wafer, removing the nitride/oxide layer where the back hole is to be formed. Now, a KOH etching is performed, using the nitride/oxide layer 26 as mask, to open the back side of the wafer as shown in FIG. 7. The etching consists of two steps. The first step is a timed etching. The second step is a selective etching of silicon using a four electrode electro-chemical etching (ECE) configuration. The N− region 14 contacts a positive electrode 32 while the P++ acoustic hole region 16 connects to a negative electrode 34. A negative electrode (counterelectrode) is inserted in the KOH solution. A reference electrode in the KOH solution provides the referential potential. By the four-electrode configuration, the N− region and the p-type substrate are inverse biased. The silicon is etched until the N− region 14 is reached. The sudden increased current in the N− region causes oxide passivation to prevent N− from being etched. The etching continues at the P++ acoustic holes because of the reverse biasing. The P++ holes are etched away, as shown by 37. The potentials of all the electrodes are required to be controlled properly. This is the key to the ECE technique. Etching stops at the nitride in frontside layer 26. Back side opening 35 is shown.

This completes formation of the perforated silicon diaphragm 40. The process of the present invention can be divided into two parts: wafer frontside processes and backside processes. The frontside processes are fully compatible with CMOS integrated circuit processes. After the CMOS integrated circuit devices and all frontside processes relating to the diaphragm fabrication have been completed, the post-process will follow to form the diaphragm and release the small holes from the wafer backside. The silicon anisotropic etching process together with the four-terminal ECE process is used to etch the backside window wherein the diaphragm thickness is controlled precisely while assuring full opening of the small holes.

Usually, the perforated silicon diaphragm is part of a MEMS device. For example, for a silicon microphone, the diaphragm serves as the backplate of a capacitor. Many of the steps described above are common processes in the device fabrication. The silicon diaphragm related process steps require only three additional masks.

The process of the present invention forms a highly perforated silicon diaphragm in a process that is compatible with the CMOS process. It is possible to integrate integrated circuits with MEMS devices in this invention. The fully silicon diaphragm of the present invention has excellent thermal and mechanical properties. Low doping in the N− area for making the P—N junction results in low stress inside the diaphragm. Other approaches use high doping. For example, the paper to P. C. Hsu et al highly dopes the silicon diaphragm with boron ions. This method results in a highly stressed diaphragm that would not apply to larger and thinner compliant membrane structures. The diaphragm of the invention is highly perforated and has precise thickness control.

The process of the present invention has been applied successfully in different MEMS projects including microphones, microrelays, and silicon cantilever. For example, the low-stress silicon relay of the present invention was free of bending while previous relays bent under zero bias making relay control difficult. Microphones fabricated using the highly perforated diaphragm of the present invention were highly sensitive and showed high performance characteristics.

The process of the present invention is distinguished over the prior arts in using selective doping to define the low stress silicon structure and using four-terminal ECE stop technology to fabricate a perforated low stress silicon diaphragm wherein the process is CMOS compatible and integratable. The post-process realizes the diaphragm and its perforation simultaneously.

While the invention has been particularly shown and described with reference to the preferred embodiments thereof, it will be understood by those skilled in the art that various changes in form and details may be made without departing from the spirit and scope of the invention.

What is claimed is:

1. A method of fabricating a perforated silicon diaphragm comprising:
providing a single crystal silicon substrate of a first conductivity type;
blanket implanting first ions of a second conductivity type opposite said first conductivity type into said single crystal silicon substrate to form an etch stop layer;
selectively implanting second ions of said first conductivity type into said single crystal silicon substrate to form a pattern of holes in a portion of said substrate;
implanting third ions of said first conductivity type overlying said pattern of holes and forming a first ohmic contact region;
implanting fourth ions of said second conductivity type not surrounding said pattern of holes to form a second ohmic contact region;
thereafter depositing a nitride layer on a frontside and a backside of said silicon substrate;
forming contacts through said nitride layer to said first and second ohmic contact regions;
thereafter patterning said backside nitride layer; and
from the backside, etching away said silicon substrate not covered by said nitride layer to said etch stop layer and simultaneously selectively etching away said pattern of holes to complete formation of said perforated diaphragm.

2. The method according to claim 1 wherein said first conductivity type is P-type and wherein said second conductivity type is N-type.

3. The method according to claim 1 wherein said first ions are N− ions, said second ions are P+ ions, said third ions are P++ ions, and said fourth ions are N++ ions.

4. The method according to claim 1 wherein said nitride layer is deposited by low pressure chemical vapor deposition.

5. The method according to claim 1 wherein said nitride layer has a thickness of between about 1000 and 1500 Angstroms.

6. The method according to claim 1 wherein said etch stop layer has a depth into said silicon substrate of between about 1 and 10 microns.

7. The method according to claim 1 wherein said step of forming contacts through said nitride layer to said first and second ohmic contact regions comprises:
etching contact openings through said nitride layer to said first and second ohmic contact regions;
depositing a metal layer within said contact openings and overlying said nitride layer; and
patterning said metal layer to form a first electrode contacting said first ohmic contact region and a second electrode contacting said second ohmic contact region.

8. The method according to claim 1 wherein said step of etching away said silicon substrate not covered by said nitride layer to said etch stop layer and simultaneously selectively etching away said pattern of holes comprises KOH with a 4 electrode electrochemical etching (ECE) configuration.

9. A method of fabricating a perforated silicon diaphragm comprising:
providing a single crystal silicon substrate of a first conductivity type;
blanket implanting first ions of a second conductivity type opposite said first conductivity type into said single crystal silicon substrate to form an etch stop layer wherein a depth of said etch stop layer into said silicon substrate determines a thickness of said perforated diaphragm;
selectively implanting second ions of said first conductivity type into said single crystal silicon substrate to form a pattern of holes in a portion of said substrate;
implanting third ions of said first conductivity type overlying said pattern of holes and forming a first ohmic contact region;
implanting fourth ions of said second conductivity type not surrounding said pattern of holes to form a second ohmic contact region;
thereafter depositing a nitride layer on a frontside and a backside of said silicon substrate;
forming contacts through said nitride layer to said first and second ohmic contact regions;
thereafter patterning said backside nitride layer; and from the backside, etching away said silicon substrate not covered by said nitride layer to said etch stop layer and simultaneously selectively etching away said pattern of holes to complete formation of said perforated diaphragm.

10. The method according to claim 9 wherein said first conductivity type is P-type and wherein said second conductivity type is N-type.

11. The method according to claim 9 wherein said first ions are N− ions, said second ions are P+ ions, said third ions are P++ ions, and said fourth ions are N++ ions.

12. The method according to claim 9 wherein said nitride layer is deposited by low pressure chemical vapor deposition.

13. The method according to claim 9 wherein said nitride layer has a thickness of between about 1000 and 1500 Angstroms.

14. The method according to claim 9 wherein said etch stop layer has a depth into said silicon substrate of between about 1 and 10 microns.

15. The method according to claim 9 wherein said step of forming contacts through said nitride layer to said first and second ohmic contact regions comprises:
etching contact openings through said nitride layer to said first and second ohmic contact regions;
depositing a metal layer within said contact openings and overlying said nitride layer; and
patterning said metal layer to form a first electrode contacting said first ohmic contact region and a second electrode contacting said second ohmic contact region.

16. The method according to claim 9 wherein said step of etching away said silicon substrate not covered by said nitride layer to said etch stop layer and simultaneously selectively etching away said pattern of holes comprises KOH with a 4 electrode electrochemical etching (ECE) configuration.

17. A method of fabricating a perforated silicon diaphragm comprising:
providing a single crystal silicon substrate of a first conductivity type;
blanket implanting at a first dose first ions of a second conductivity type opposite said first conductivity type into said single crystal silicon substrate to form an etch stop layer wherein a depth of said etch stop layer into said silicon substrate determines a thickness of said perforated diaphragm;
selectively implanting at a second dose second ions of said first conductivity type into said single crystal silicon substrate to form a pattern of holes in a portion of said substrate;
implanting at a third dose third ions of said first conductivity type overlying said pattern of holes and forming a first ohmic contact region; implanting at a fourth dose fourth ions of said second conductivity type not surrounding said pattern of holes to form a second ohmic contact region;
thereafter depositing a nitride layer on a frontside and a backside of said silicon substrate;
forming contacts through said nitride layer to said first and second ohmic contact regions;
thereafter patterning said backside nitride layer; and
from the backside, etching away said silicon substrate not covered by said nitride layer to said etch stop layer and simultaneously selectively etching away said pattern of holes to complete formation of said perforated diaphragm.

18. The method according to claim 17 wherein said first dose is lower than then second, third, and fourth doses.

19. The method according to claim 17 wherein said first conductivity type is P-type and wherein said second conductivity type is N-type.

20. The method according to claim 17 wherein said first ions are N− ions, said second ions are P+ ions, said third ions are P++ ions, and said fourth ions are N++ ions.

21. The method according to claim 17 wherein all of said steps up to said patterning said backside nitride layer step can be CMOS compatible processes.

22. The method according to claim 17 wherein said etch stop layer has a depth into said silicon substrate of between about 1 and 10 microns.

23. The method according to claim 17 wherein said step of forming contacts through said nitride layer to said first and second ohmic contact regions comprises:
etching contact openings through said nitride layer to said first and second ohmic contact regions;
depositing a metal layer within said contact openings and overlying said nitride layer; and
patterning said metal layer to form a first electrode contacting said first ohmic contact region and a second electrode contacting said second ohmic contact region.

24. The method according to claim 17 wherein said step of etching away said silicon substrate not covered by said nitride layer to said etch stop layer and simultaneously selectively etching away said pattern of holes comprises KOH with a 4 electrode electrochemical etching (ECE) configuration.

25. The method according to claim 23 wherein said step of implanting at a third dose third ions of said first conductivity type overlying said pattern of holes connects said pattern of holes together to provide external electric biases for said ECE configuration.
